(19) United States
(12) Patent Application Publication
(10) Pub. No.: US 2017/0141228 A1
(43) Pub. Date: May 18, 2017

(54) FIELD EFFECT TRANSISTOR AND MANUFACTURING METHOD THEREOF

(71) Applicant: Taiwan Semiconductor Manufacturing Co., Ltd., Hsinchu (TW)

(72) Inventors: Austin Hsu, New Taipei City (TW); Ching Yu, Hsinchu City (TW); Ernest Chiu, Hsinchu City (TW)

(21) Appl. No.: 14/941,669

(22) Filed: Nov. 16, 2015

(51) Int. Cl. H01L 29/78; H01L 29/165; H01L 29/66

(52) U.S. Cl. CPC H01L 29/7848; H01L 29/66636; H01L 29/165

(57) ABSTRACT

A field effect transistor comprising a substrate, at least one gate structure, spacers and strained source and drain regions is described. The at least one gate structure is disposed on the substrate and between the recesses and the isolation structures. The spacers are disposed on sidewalls of the at least one gate structure. The strained source and drain regions are disposed in the recesses and on two opposite sides of the at least one gate structure, and top edges of the strained source and drain regions are covered by the spacers and located beneath the spacers.

### BACKGROUND

As the linewidth of the semiconductor devices keeps scaling down, the gate width and the channel length of the planar CMOS-compatible semiconductor devices, such as metal-oxide-semiconductor field effect transistors (MOSFETs), keeps shrinking. The strained-silicon technology is utilized to change the mobility of electrons or holes in the channel so as to increase the operation speed of the transistor.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of an exemplary MOSFET in accordance with some embodiments of the present disclosure.

FIGS. 2A-2E are the cross-sectional views showing the MOSFET at various stages of the manufacturing method for forming a MOSFET according to some embodiments of the present disclosure.

FIG. 3 is an exemplary flow chart showing the process steps of the manufacturing method for forming a MOSFET in accordance with some embodiments of the present disclosure.

### DETAILED DESCRIPTION

The following disclosure provides many different embodiments or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The embodiments of the present disclosure describe the exemplary manufacturing processes of MOSFETs and the MOSFETs fabricated there-from. The MOSFET may be formed on a monocrystalline semiconductor substrate, such as a bulk silicon substrate in certain embodiments of the present disclosure. In some embodiments, the MOSFET may be formed on a silicon-on-insulator (SOI) substrate or a GOI (germanium-on-insulator) substrate as alternatives. Also, in accordance with the embodiments, the silicon substrate may include other conductive layers, doped regions or other semiconductor elements, such as transistors, diodes or the like. The embodiments are not used to limit the contexts.

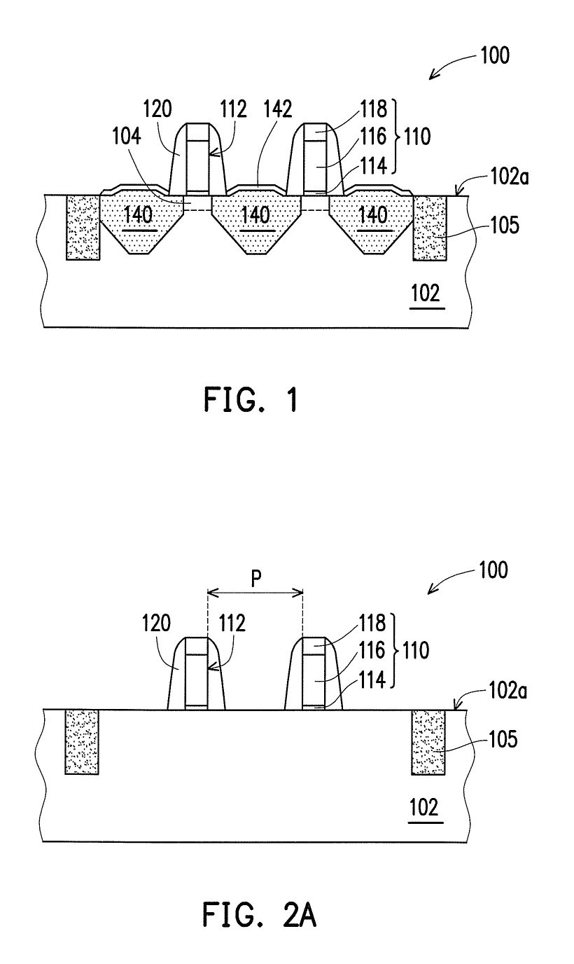

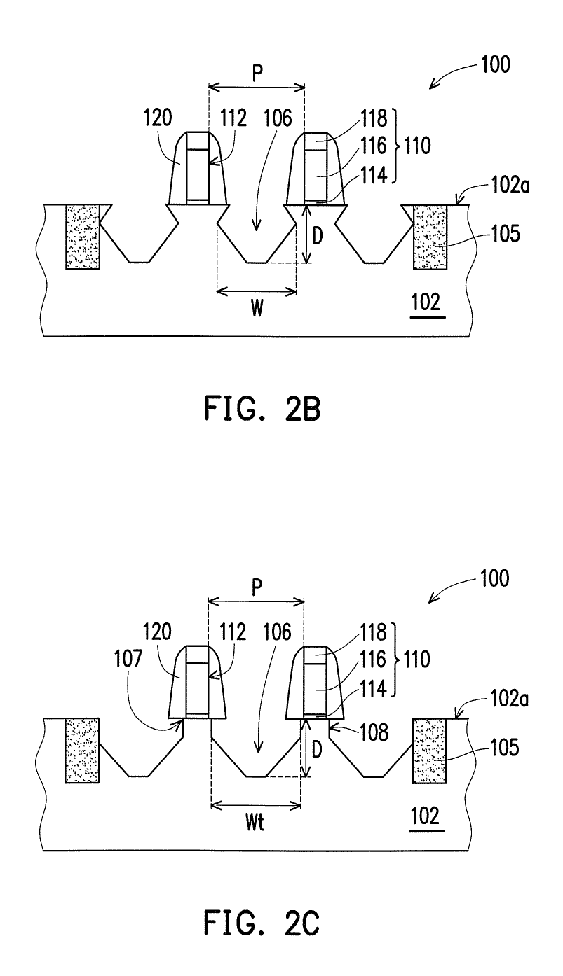

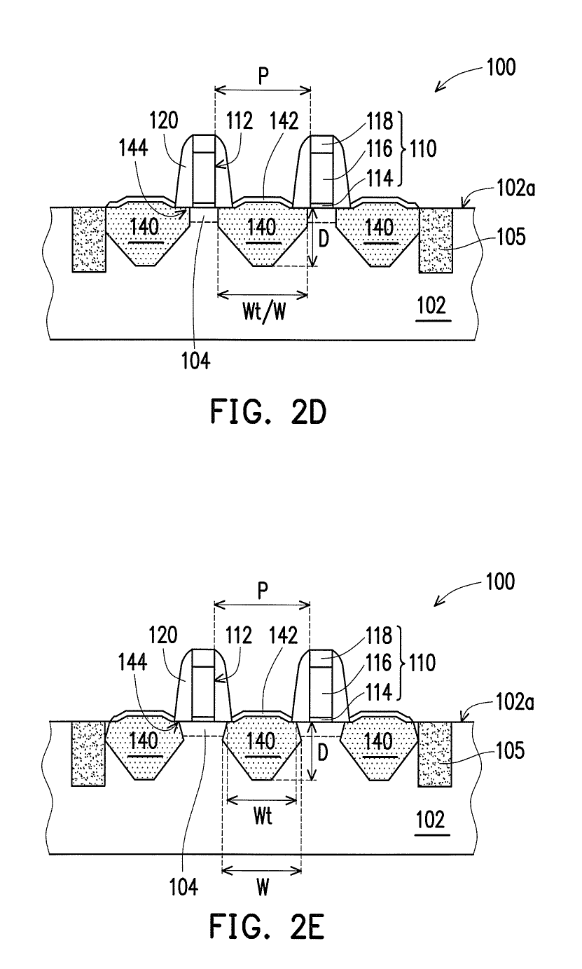

FIG. 1 illustrates a cross-sectional view of an exemplary MOSFET in accordance with some embodiments of the present disclosure. FIG. 2A-2E illustrates the MOSFET at various stages of the manufacturing methods for forming a MOSFET according to some embodiments of the present disclosure. In FIG. 1, the MOSFET 100 comprises at least one gate structure 110 formed on a substrate 102, spacers 120 formed on opposite sidewalls 112 of the gate structure 110, a channel region 104 located between the spacers 120 and strained source and drain regions 140 formed within recesses 106 of the substrate 102. The strained source and drain regions 140 are located at two opposite sides of the gate structure 110. In some embodiments, the MOSFET 100 is a p-channel MOSFET. In some embodiments, the MOSFET 100 is an n-channel MOSFET.

In FIG. 2A, a substrate 102 is provided. The substrate 102 is a monocrystalline semiconductor substrate or a SOI substrate, for example. In some embodiments, the substrate 102 is a silicon substrate. The substrate 102 includes isolation structures 105 for electrical isolation and the MOSFET 100 is intended to be located between the isolation structures 105. In some embodiments, the isolation structures 105 are trench isolation structures. The trench isolation structures are strip-shaped and arranged in parallel, for example. The trench isolation structures are filled with a dielectric material, such as silicon oxide or spin-on materials, formed by methods known in the art.

Referring to FIG. 2A, the gate structures 110 are formed on the substrate 102 and between the isolation structures 105. In some embodiments, the gate structures 110 are strip-shaped structures arranged in parallel. In FIG. 2B, two gate structures 110 are shown, and the number of the gate structures 110 are for illustrative purposes but not intended to limit the structure of the present disclosure. In some embodiments, the gate structure 110 comprises a gate dielectric strip 114, a gate electrode strip 116 located on the gate dielectric strip 114, and a hard mask strip 118 located on the gate electrode strip 116. Also, the spacers 120 located on opposite sidewalls of the gate electrode strip 116 and the hard mask strip 118. In some embodiments, the gate structures 110 are formed by forming a gate dielectric layer (not shown), depositing a gate electrode material layer (not shown), a hard mask layer (not shown) over the gate electrode material layer and then patterning the hard mask layer, the gate electrode material layer and the gate dielectric layer to form the gate dielectric strips 114, the gate electrode strips 116 and the hard mask strips 118. In some embodiments, the gate structure 110 is a polysilicon gate structure or a replacement metal gate structure. The material of the gate electrode strip 116 comprises either doped or undoped polysilicon or a metal-containing conductive material. The metal-containing conductive material comprises aluminum (Al), copper (Cu), tungsten (W), cobalt (Co), titanium (Ti), tantalum (Ta), ruthenium (Ru), TiN, TiAl, TiAlN, TaN, TaC, NiSi, CoSi or a combination thereof. In some embodiments, the material of gate dielectric strip 114 comprises silicon oxide, silicon oxynitride, silicon nitride or the combination thereof. In some embodiments, the material of gate dielectric strip 114 comprises a high-k dielectric material, and the high-k dielectric material has a k value greater than about 7.0 and includes a metal oxide or a silicate of hafnium (Hf), Al, zirconium (Zr), lanthanum (La), magnesium (Mg), barium (Ba), Ti, lead (Pb) and combinations thereof. Depending on whether the MOSFET 100 is a p-channel MOSFET or an n-channel MOSFET, the materials of the gate dielectric strips 114 and/or the gate electrode strips 116 are chosen based on the product requirements. In one embodiment, the hard mask strips 118 are formed of silicon nitride, silicon oxide or the combination thereof, for example. In some embodiments, the spacers 120 are formed of silicon nitride or other insulating materials. The spacers 120 may be a single layer or a multilayered structure. In some embodiments, the spacers 120 are formed by depositing a blanket layer of a dielectric material (not shown) and performing an anisotropic etching process to form the spacers 120 on both sides of the gate structure 110.

In FIG. 2B, recesses 106 are formed within the substrate 102 beside the gate structure 110 and the spacers 120 by removing a portion of the substrate 102 at the locations intended for source and drain regions and using the gate structure 110 and the spacers 120 as the etching masks. The recesses 106 are formed by using one or more etching processes, including anisotropic etching, isotropic etching or the combination thereof. In some embodiments, the formation of the recesses 106 comprises a main etching process including a trench etching process and a lateral etching process. The substrate 102 is etched downward with the trench etching process to a depth D (accounting from the top surface 102a of the substrate 102) and the substrate 102 is further etched laterally with the lateral etching process to a width W (measuring from the widest portion of the recess 106) to form the recesses 106. In some embodiments, the width W of the recesses 106 is substantially equivalent to or less than the spacing P between the two most adjacent gate structures 110. The depth D is more than 60 nanometers and may range from 70 nanometers to 80 nanometers, for example. In some embodiments, the recesses 106 are etched with the trench etching process to form U-shaped etch profiles or V-shaped etch profiles and followed by the lateral etching process to form diamond-shaped recess profiles. The trench etching process or the lateral etching process includes one or more anisotropic etching processes, isotropic etching processes, reactive ion etching (RIE) processes, or a combination thereof. Such processes optionally include bombarding the substrate 102 with ions (e.g., fluorocarbons, oxygen, chlorine, nitrogen, argon, helium, etc.) to dope or amorphize portions of the substrate 102.

In some embodiments, as shown in FIG. 2C, following the main etching process, the formation of the recesses 106 further comprises a side etching process to widen the upper edges of the recesses 106. The side etching process is controlled to laterally removes the substrate 102 under the spacers 120 so that the upper edges 107 of the recesses 106 extend toward the channel region under the gate structure 110 and outspreads below the spacers 120. In some embodiments, the bucket-shaped recess 106 has an upper side 108 adjacent to the channel region 104 (FIG. 2D) and substantially perpendicular to (normal to) the top surface 102a of the substrate 102 as shown in FIG. 2C. That is, the top dimension Wt (measuring between the upper edges 107) of the widened recesses 106 is substantially equivalent to the width W of the recesses 106. In alternative embodiments, the bucket-shaped recess 106 has an upper side 108 adjacent to the channel region 104 and angled at an angle (other than normal) to the top surface 102a of the substrate 102. Still, the upper side 108 of the recess 106 at most is aligned with the sidewalls 112 of the gate structure 110. That is, the top dimension Wt (measuring between the upper edges 107) of the widened recesses 106 is smaller than the width W and the width W is substantially equivalent to or less than the spacing P between the two most adjacent gate structures 110. The diamond-shaped recess profile of the recess 106 in FIG. 2B, after the side etching process performed to the recess 106, becomes or changes into a bucket-shaped recess profile of the recess 106 as shown in FIG. 2C. The side etching process includes one or more anisotropic etching processes, isotropic etching processes or a combination thereof. In some embodiments, the side etching process is performed by using an etching gas including hydrogen chloride (HCl), germanium hydride (GeH₄), other suitable etching gases or a combination thereof. The flow rate of the etching gas, the pressure and/or the etching temperature of the side etching process is adjustable to control the etching of the substrate not extending beyond the gate structure(s). Such etching process can remove a portion of the substrate 102 including dislocations near corners of the spacers 120.

In some embodiments, after the formation of the recesses 106 of FIG. 2C within the substrate 102, the strained source and drain regions 140 are formed by depositing a strained material within the recesses 106 to fill the recesses 106, as shown in FIG. 2D. In some embodiments, some of the strained source and drain regions 140 are substantially coplanar with or slightly protruded from the top surface 102a of the substrate 102. In addition, capping layers 142 are formed on the strained source and drain regions 140 as contact terminals. In some embodiments, the material of the capping layers 142 comprises silicon-containing material doped with boron, for example. The thickness of the capping layers 142 is adjustable according to the requirement of the electrical property of the device. In some embodiments, the strained source and drain regions 140 are optionally formed with silicide layers (not shown) by silicidation.

In certain embodiments, the strained material is a germanium-containing material, such a silicon germanium (SiGe) or a carbon-containing material such as silicon carbide (SiC). The strained material deposited within the recesses 106 (source and drain regions) is a stress-inducing material, which causes a uniaxial compressive strain to the channel region. The strained material, such as SiGe, is utilized for hole mobility enhancement of a p-channel MOSFET. For improving carrier mobility of the p-channel MOSFET at higher node development, such as node-28 and below, the content of Ge in SiGe may be adjusted to be within a specific range. Similarly, the strained material, such as SiC, is utilized for electron mobility enhancement of an n-channel MOSFET. In some embodiments, the strained source and drain regions 140 are formed through epitaxial growth. In some embodiments, the epitaxial growth technology comprises low pressure CVD (LPCVD), atomic layer CVD (ALCVD), ultrahigh vacuum CVD (UHVCVD), reduced pressure CVD (RPCVD), molecular beam epitaxy (MBE), metalorganic vapor phase epitaxy (MOVPE) or a combination thereof. Alternatively, epitaxial growth technology utilizes cyclic deposition-etch (CDE) epitaxy process or selective epitaxial growth (SEG) process to form the strained material of high crystal quality. In one embodiment, the material of the strained source and drain regions 140 comprises boron-doped SiGe formed by selectively growing epitaxy with in-situ doping. In one embodiment, the capping layer 142 is formed as part of epitaxial growth of the strained material filling into the recesses 106, but the capping layer 142 is formed with a different material composition from the strained material.

Since the strained source and drain regions 140 are located on opposite sides of the channel region 104 and the lattice constant of the strained material is different from the material of the substrate 102, the channel region 104 is strained or stressed to increase carrier mobility of the device and enhance the device performance.

In FIG. 2D, more than one of the strained source and drain regions 140 filled within the recesses 106 correspondingly have bucket-shaped profiles. The top edges 144 of the strained source and drain regions 140 are covered by the spacers 120 and located below the spacers 120 and beside the channel region 104 under the gate structure 110. The top edges 144 of the strained source and drain regions 140 at most are aligned with the sidewalls 112 of the gate structure 110. That is, the top dimension Wt of the strained source and drain regions 140 is substantially equivalent to or less than the spacing P between the two most adjacent gate structures 110. The strained source and drain regions 140 in FIG. 2D have bucket-shaped profiles, narrower at the bottom and wider at the middle and the top. For the strained source and drain regions 140, the width W (measuring from the widest portion thereof) is substantially equivalent to the top dimension Wt and is substantially equivalent to or less than the spacing P of the gate structures 110.

In some embodiments, after the formation of the bucket-shaped recesses 106 within the substrate 102, the strained source and drain regions 140 are formed by filling up the recesses 106 with a strained material, as shown in FIG. 2E. The main differences between FIG. 2D and FIG. 2E lie in that the shapes of the recesses 106 are different and the shapes of the resultant strained source and drain regions 140 are different. In some embodiments, the upper side 108 of the bucket-shaped recess 106 is not perpendicular to, but angled at an angle relative to the top surface 102a of the substrate 102. That is, the top dimension Wt of the widened recesses 106 is smaller than the width W of the recesses 106. Accordingly, the top dimension Wt of the strained source and drain regions 140 is smaller than the width W of the strained source and drain regions 140, and the width W is substantially equivalent to or less than the spacing P of the gate structures 110. In some embodiments, some of the strained source and drain regions 140 are substantially coplanar with or slightly protruded from the top surface 102a of the substrate 102. In some embodiments, the capping layers 142 are formed on the strained source and drain regions 140 as contact terminals. Also, the strained source and drain regions 140 are optionally formed with silicide layers (not shown) by silicidation.

In the above embodiments, the etching profile of the recess 106 is well controlled so that the upper edge(s) of the recess 106 extends toward the channel region 104 and extends below the spacers 120. The upper edge(s) 107 of the recess 106 is at most aligned with the sidewall of the gate structure 110 and will not contact the gate structure 110 or the channel region 104. As the etching profile(s) of the recesses is well controlled, the shape of the recesses is well tuned and optimized for stress enhancement. The profiles of the recesses are controlled to ensure the shape of the later filled strained material enhances the desired stress in the channel region. For the devices with a narrow spacing, it is possible to increase the width of the strained material portions without compromising the proximity profile thereof. Thus, the strained source and drain regions in accordance with the above embodiments of the present disclosure allow maximal channel strain and the performance of the device is enhanced. Also, the proximity profile of the strained source and drain regions in accordance with the above embodiments of the present disclosure keeps constant.

Accordingly, the strained source and drain regions 140 formed within the recesses 106 have bucket-shaped sidewall profiles, so that the width W (measuring from the widest portion thereof) is substantially equivalent to or slight larger than the top dimension Wt of the strained source and drain regions 140 and is substantially equivalent to or less than the spacing P of the gate structures 110. The top edges 144 of the strained source and drain regions 140 are located below the spacers 120 and beside the channel region 104 under the gate structure 110. The top edges 144 of the strained source and drain regions 140 at most are aligned with the sidewalls 112 of the gate structure 110. As the top edges 144 of the strained source and drain regions 140 extend beyond and beneath the spacers, more stress can be imposed upon the channel region to adjust the carrier mobility of the MOSFET and the performance of the device is boosted.

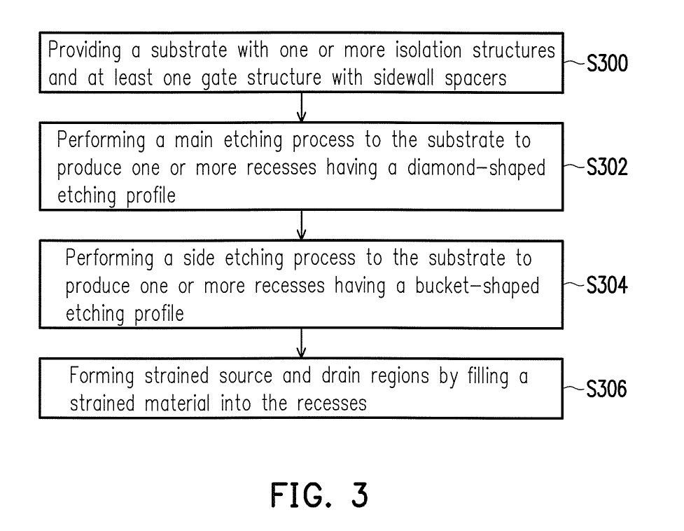

FIG. 3 is an exemplary flow chart showing some of the process steps of the manufacturing method for forming a MOSFET in accordance with some embodiments of the present disclosure.

Although the steps of the method are illustrated and described as a series of acts or events, it will be appreciated that the illustrated ordering of such acts or events are not to be interpreted in a limiting sense. In addition, not all illustrated process or steps are required to implement one or more embodiments of the present disclosure.

In Step 300, a substrate is provided with one or more isolation structures and at least one gate structure with sidewall spacers. The substrate is a silicon substrate or a silicon-on-insulator (SOI) substrate. In Step 302, a main etching process is performed to the substrate to produce one or more recesses having a diamond-shaped etching profile. In some embodiments, the main etching process comprises one or more anisotropic etching processes, isotropic etching processes, RIE processes or a combination thereof. In Step 304, a side etching process is performed to the substrate to produce one or more recesses having a bucket-shaped etching profile. The side etching process comprises one or more anisotropic etching processes, isotropic etching processes or a combination thereof. In Step 306, strained source and drain regions are formed by filling a strained material to fill up the recesses. The strained material comprise a germanium-containing material or a carbon-containing material. A width W of the strained source and drain regions (measuring from the widest portion thereof) is substantially equivalent to a top dimension Wt of the strained source and drain regions and is substantially equivalent to or less than a spacing P between the gate structures.

In the above embodiments, the etching profile of the recesses can be well controlled through the main etching process and the side etching process. For the device having the gate structures arranged with tight pitch or spacing, the etching profile, including the diamond-shaped or the bucket-shaped profile, of the recess(es) is suitable for stress enhancement without compromising the proximity profile. Since the profile of the recesses are well tuned, the profile of the strained source and drain regions is suitable to impart more stress on the channel region and the electrical performance of the device is boosted.

In some embodiments of the present disclosure, a field effect transistor is described. The field effect transistor comprises a substrate having isolation structures and recesses, at least one gate structure, spacers and stained source and drain regions. The at least one gate structure is disposed on the substrate and between the recesses and the isolation structures. The spacers are disposed on sidewalls of the at least one gate structure. The strained source and drain regions are disposed in the recesses and located on opposite sides of the at least one gate structure. Top edges of the strained source and drain regions extends beyond and below the spacers and are located beside the sidewalls of the gate structure.

In some embodiments of the present disclosure, a field effect transistor is described. The field effect transistor comprises a substrate having isolation structures, gate structure, spacers, stained source and drain regions and capping layers. The gate structures are disposed on the substrate and between the isolation structures, and the spacers are disposed on sidewalls of the gate structures. The strained source and drain regions are disposed within recesses of the substrate and located on opposite sides of the gate structures. The spacers cover top edges of the strained source and drain regions beneath the spacers. The capping layers are located on the strained source and drain regions.

In some embodiments of the present disclosure, a method for forming a field effect transistor is described. A substrate having isolation structures and gate structures and spacers on sidewalls of the gate structures is provided. A main etching process is performed to the substrate to produce one or more recesses having a diamond-shaped etching profile. A side etching process is performed to the substrate to remove the substrate under the spacers to produce one or more recesses having a bucket-shaped etching profile. Strained source and drain regions filled in the one or more recesses having the bucket-shaped etching profile are then formed.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A field effect transistor, comprising:
a substrate having isolation structures and recesses;
at least one gate structure, disposed on the substrate and between the recesses and the isolation structures;
spacers, disposed on sidewalls of the at least one gate structure; and
strained source and drain regions, disposed in the recesses and located on opposite sides of the at least one gate structure, wherein top edges of the strained source and drain regions extends beyond and below the spacers and are located beside the sidewalls of the at least one gate structure, and portions of the strained source and drain regions adjacent to the isolation structures have top surfaces coplanar with and leveled with a top surface of the substrate.

2. The transistor of claim 1, further comprising capping layers located on the strained source and drain regions.

3. The transistor of claim 2, wherein a material of the strained source and drain regions comprises boron-doped silicon germanium and a material of the capping layers comprises a silicon-containing material doped with boron.

4. The transistor of claim 1, wherein at least one of the strained source and drain regions has a bucket-shaped profile, and a top dimension of the at least one of the strained source and drain regions is smaller than a width of the at least one of the strained source and drain regions.

5. The transistor of claim 1, wherein at least one of the strained source and drain regions has a bucket-shaped profile, and a top dimension of the at least one of the strained source and drain regions is substantially equivalent to a width of the at least one of the strained source and drain regions.

6. The transistor of claim 1, wherein the at least one gate structure is a polysilicon gate structure or a replacement metal gate structure.

7. A field effect transistor, comprising:
a substrate having isolation structures;
gate structures, disposed on the substrate and between the isolation structures;
spacers, disposed on sidewalls of the gate structures;
strained source and drain regions, disposed within recesses of the substrate and located on opposite sides of the gate structures, wherein the spacers cover top edges of the strained source and drain regions beneath the spacers, and portions of the strained source and drain regions adjacent to the isolation structures have top surfaces coplanar with and leveled with a top surface of the substrate; and
capping layers located on the strained source and drain regions.

8. The transistor of claim 7, wherein at least one of the strained source and drain regions has a bucket-shaped profile, and a top dimension of the at least one of the strained source and drain regions is smaller than a width of the at least one of the strained source and drain regions, and the width of the at least one of the strained source and drain regions is substantially equivalent to or smaller than a spacing of the gate structures.

9. The transistor of claim 7, wherein at least one of the strained source and drain regions has a bucket-shaped profile, and a top dimension of the at least one of the strained source and drain regions is substantially equivalent to a width of the at least one of the strained source and drain regions, and the width of the at least one of the strained source and drain regions is substantially equivalent to or smaller than a spacing of the gate structures.

10. The transistor of claim 7, wherein a material of the strained source and drain regions comprises boron-doped silicon germanium and a material of the capping layers comprises silicon doped with boron.

11. The transistor of claim 7, wherein the gate structure comprises:
a gate dielectric strip disposed on the substrate;
a gate electrode strip disposed on the gate dielectric strip; and
a hard mask strip disposed on the gate electrode strip.

12-20. (canceled)

21. A field effect transistor, comprising:
a substrate having isolation structures and recesses located between the isolation structures;
gate structures, disposed on the substrate and between the isolation structures;
spacers disposed on sidewalls of the gate structures;
strained source and drain regions, disposed on opposite sides of the gate structures, disposed in the recesses of the substrate and located between the isolation structures, wherein portions of the strained source and drain regions are located right beneath the spacers and are in contact with the spacers, and portions of the strained source and drain regions adjacent to the isolation structures have top surfaces coplanar with and leveled with a top surface of the substrate; and
contact terminals located on the strained source and drain regions.

22. The transistor of claim 21, wherein a material of the strained source and drain regions comprises boron-doped silicon germanium and a material of the contact terminals comprises a silicon-containing material doped with boron.

23. The transistor of claim 21, wherein at least one of the strained source and drain regions has a bucket-shaped profile, and a top dimension of the at least one of the strained source and drain regions is smaller than a width of the at least one of the strained source and drain regions measuring from a widest portion thereof.

24. The transistor of claim 23, wherein the width of the at least one of the strained source and drain regions measuring from the widest portion thereof is substantially equivalent to a spacing of the gate structures measuring from the sidewalls of two most adjacent gate structures.

25. The transistor of claim 23, wherein the width of the at least one of the strained source and drain regions measuring from the widest portion thereof is less than a spacing of the gate structures measuring from the sidewalls of two most adjacent gate structures.

26. The transistor of claim 21, wherein the gate structures are polysilicon gate structures or replacement metal gate structures.

27. The transistor of claim 21, wherein the isolation structures are trench isolation structures.

28. The transistor of claim 21, wherein the spacers are multi-layered structures.
